(19) United States
(12) Patent Application Publication
(10) Pub. No.: US 2024/0314978 A1
(43) Pub. Date: Sep. 19, 2024

(54) COOLING DEVICE

(71) Applicant: NIDEC CORPORATION, Kyoto (JP)

(72) Inventors: Kengo INOUE, Kyoto (JP); Yuta HORI, Kyoto (JP)

(21) Appl. No.: 18/396,712

(22) Filed: Dec. 27, 2023

(30) Foreign Application Priority Data
Mar. 17, 2023 (JP) 2023-042639

(51) Int. Cl. H05K 7/20

(52) U.S. Cl. CPC H05K 7/20409; H05K 7/20263

(57) ABSTRACT

A heat radiating fin part includes at least one protrusion protruding toward a first side in a first direction and being provided at an end of the heat radiating fin part on the first side in the first direction, the end allowing a refrigerant supplied through a liquid cooling jacket to flow into the end. The at least one protrusion is provided on at least one of a first side in the second direction with respect to a center position of the heat radiating fin part in the second direction. At least a part of a semiconductor element provided on a base part on a second side is disposed closer to a center position in the second direction than the protrusion provided closest to the center position in the second direction on the first side in the second direction.

### CROSS-REFERENCE TO RELATED APPLICATIONS

The present invention claims priority under 35 U.S.C. § 119 to Japanese Patent Application No. 2023-042639 filed on Mar. 17, 2023, the entire content of which is incorporated herein by reference.

### FIELD OF THE INVENTION

The present disclosure relates to a cooling device.

### BACKGROUND

Heat radiating members are conventionally used for cooling heating elements. The heat radiating members each includes a base part and a plurality of fins. The plurality of fins protrudes from the base part. The heat radiation members each can be installed in a liquid cooling jacket. The base part and the liquid cooling jacket form a flow path. When a refrigerant flows through the flow path, heat of a heating element moves to the refrigerant.

Between the fins and the liquid cooling jacket, a certain gap (clearance) needs to be provided. When no gap is provided, the fins may be deformed when the base part is attached to the liquid cooling jacket, and desired cooling performance may not be obtained. Additionally, the fins may not be accommodated in the liquid cooling jacket due to positional variation when the fins are fixed to the base part or assembly tolerance of the fins.

For this reason, a certain gap is provided in advance between the fins and the liquid cooling jacket. Unfortunately, when a large amount of the refrigerant flows into this gap, an inflow of the refrigerant into a space between the fins decreases to result in arising a problem that the ability to cool the fins deteriorates.

### SUMMARY

An exemplary cooling device of the present disclosure includes a liquid cooling jacket and a heat radiating member installed in the liquid cooling jacket. The heat radiating member includes: a base part in a plate shape that extends in a first direction along a refrigerant flow direction and in a second direction orthogonal to the first direction and has a thickness in a third direction orthogonal to the first direction and the second direction; and a heat radiating fin part formed by stacking a plurality of fins in the second direction, the plurality of fins protruding from the base part toward a first side in the third direction and extending in the first direction. The liquid cooling jacket includes side wall parts disposed with gaps in the second direction from respective ends of the heat radiating fin part in the second direction. The heat radiating fin part includes at least one protrusion protruding toward a first side in the first direction and being provided at an end of the heat radiating fin part on the first side in the first direction, the end allowing a refrigerant supplied through the liquid cooling jacket to flow into the end. When viewed from the first side in the third direction, the at least one protrusion is provided on at least one of a first side in the second direction and a second side in the second direction with respect to a center position of the heat radiating fin part in the second direction. When viewed from the first side in the third direction, at least a part of the semiconductor element provided on the base part on a second side in the third direction is disposed closer to the center position in the second direction than the protrusion provided closest to the center position in the second direction on the first side in the second direction or the second side in the second direction with respect to the center position in the second direction, or on each of the first side in the second direction and the second side in the second direction with respect to the center position in the second direction.

The above and other elements, features, steps, characteristics and advantages of the present disclosure will become more apparent from the following detailed description of the preferred embodiments with reference to the attached drawings.

### BRIEF DESCRIPTION OF THE DRAWINGS

FIG. 1 is an exploded perspective view of a cooling device according to an exemplary embodiment of the present disclosure;

FIG. 2 is an exploded perspective view of a cooling device according to an exemplary embodiment of the present disclosure;

FIG. 3 is a side sectional view of a cooling device according to an exemplary embodiment of the present disclosure;

FIG. 4 is a perspective view of a heat radiating member according to an exemplary embodiment of the present disclosure;

FIG. 5 is a schematic plan view according to a first embodiment;

FIG. 6 is a schematic plan view according to a second embodiment;

FIG. 7 is a schematic plan view according to a third embodiment;

FIG. 8 is a schematic plan view according to a fourth embodiment;

FIG. 9 is a partial perspective view of a heat radiating member for illustrating a height of a protrusion;

FIG. 10 is a partially exploded perspective view of a cooling device according to a modification; and

FIG. 11 is a schematic plan view according to a modification.

### DETAILED DESCRIPTION

Hereinafter, an exemplary embodiment of the present disclosure will be described with reference to the drawings.

The drawings each indicate a first direction as an X direction in which X1 indicates a first side in the first direction and X2 indicates a second side in the first direction. The first direction is along a direction F in which a refrigerant WT flows, and F2 indicates a downstream side and F1 indicates an upstream side. The first direction is orthogonal to a second direction as a Y direction in which Y1 indicates a first side in the second direction, and Y2 indicates a second side in the second direction. The first direction and the second direction are orthogonal to a third direction as a Z direction in which Z1 indicates a first side in the third direction, and Z2 indicates a second side in the third direction. The above-described orthogonal also includes intersection at an angle slightly shifted from 90 degrees. Each of the above-described directions does not limit a direction when a cooling device 150 is incorporated in various devices.

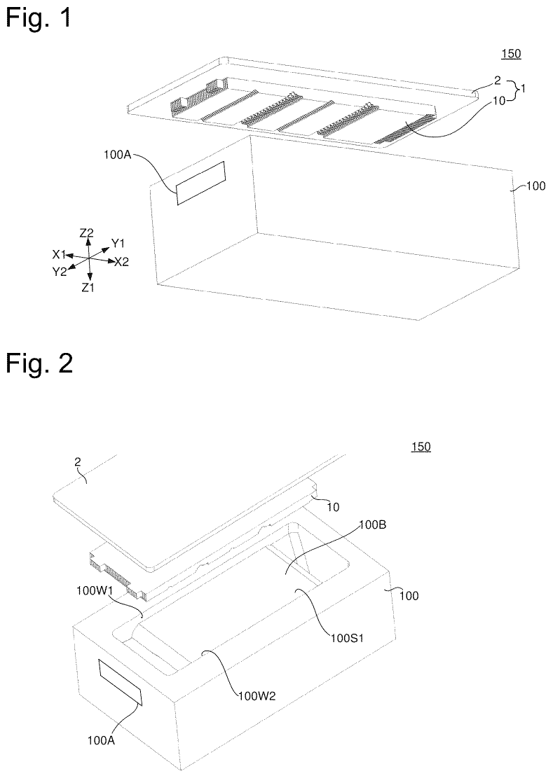

FIGS. 1 and 2 are each an exploded perspective view of the cooling device 150 according to an exemplary embodiment of the present disclosure. FIG. 2 allows the inside of a liquid cooling jacket 100 to be visually recognized.

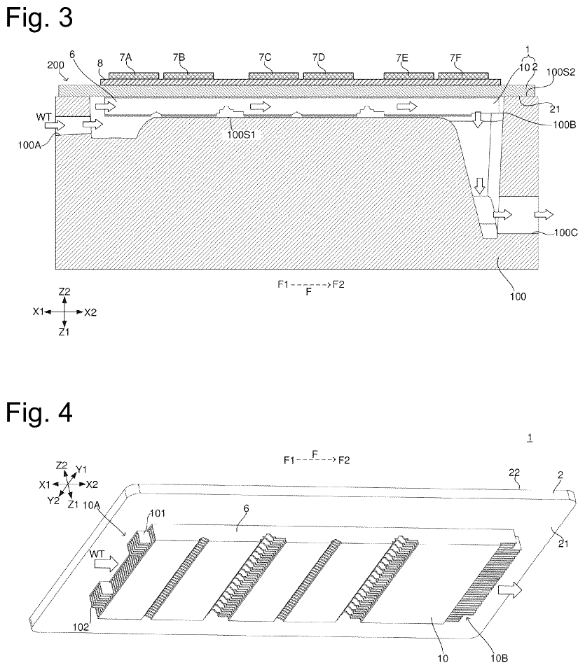

FIG. 3 is a side sectional view of the cooling device 150. FIG. 3 is a diagram of the cooling device 150 taken along a cutting plane orthogonal to the second direction at an intermediate position in the second direction and viewed from a first side in the second direction toward the second side in the second direction.

The cooling device 150 includes the liquid cooling jacket 100 and a heat radiating member 1 installed in the liquid cooling jacket 100. FIG. 3 illustrates a flow of the refrigerant WT. A first side (X1) in the first direction is an upstream side in a direction in which the refrigerant WT flows, and the second side (X2) in the first direction is a downstream side in the direction in which the refrigerant WT flows. The refrigerant WT is liquid such as water.

The cooling device 150 is for cooling a plurality of semiconductor elements 7A, 7B, 7C, 7D, 7E, and 7F (referred to below as 7A and the like). The semiconductor elements 7A and the like are each a power transistor of an inverter provided in a traction motor for driving wheels of a vehicle, for example. The power transistor is an insulated gate bipolar transistor (IGBT), for example. In this case, the cooling device 150 is mounted on the traction motor. The number of semiconductor elements may be a plural number other than six, or may be singular.

The semiconductor elements 7A and the like are mounted on an insulating circuit board 8. The insulating circuit board 8 is disposed on a base part 2 described later. The insulating circuit board 8 may be divided into a plurality of parts.

The heat radiating member 1 includes a heat radiating fin part 10 and the base part 2. The heat radiating fin part 10 is fixed to the base part 2 on the first side in the third direction. The liquid cooling jacket 100 includes a first flow path 100A on an inlet side, a second flow path 100B, and a third flow path 100C on an outlet side.

The first flow path 100A is disposed on a first side in the first direction in the liquid cooling jacket 100 and passes through the liquid cooling jacket 100 in the first direction. The second flow path 100B extends in the first direction. The second flow path 100B is connected at its end on the first side in the first direction to the first flow path 100A.

The third flow path 100C is disposed on the second side in the first direction in the liquid cooling jacket 100 and passes through the liquid cooling jacket 100 in the first direction. The second flow path 100B is connected at its end on the second side in the first direction to the third flow path 100C.

When the heat radiating member 1 is not attached to the liquid cooling jacket 100, a bottom surface 100S1 of the second flow path 100B is exposed to the second side in the third direction (FIG. 2). The heat radiating member 1 is attached to the liquid cooling jacket 100 by fixing a surface 21 of the base part 2 on the first side in the third direction in the heat radiating member 1 to a surface 100S2 of the liquid cooling jacket 100 on the second side in the third direction. When the heat radiating member 1 is attached, the second side of the bottom surface 100S1 in the third direction is covered with the base part 2. As a result, the second flow path 100B is closed by the base part 2.

When the heat radiating member 1 is attached to the liquid cooling jacket 100, the heat radiating fin part 10 is disposed inside the second flow path 100B. The heat radiating fin part 10 is formed by stacking a plurality of fins 6 in the second direction as described later. Between the heat radiating fin part 10 and the bottom surface 100S1, a gap (clearance) in the third direction is formed.

The refrigerant WT having flowed from the outside of the liquid cooling jacket 100 into the first flow path 100A flows through the first flow path 100A and then flows into the second flow path 100B. The refrigerant WT flowing through the second flow path 100B toward the first side in the first direction flows into the third flow path 100C. The refrigerant WT flowing through the third flow path 100C toward the first side in the third direction is discharged to the outside of the liquid cooling jacket 100.

The insulating circuit board 8 is disposed on the base part 2 on the second side in the third direction. The semiconductor element 7A is disposed on the insulating circuit board 8. The semiconductor elements 7A and the like generate heat that moves from the heat radiating fin part 10 to the refrigerant WT flowing inside the second flow path 100B through the insulating circuit board 8 to cool the semiconductor elements 7A and the like. The semiconductor elements 7A and the like, the insulating circuit board 8, and the heat radiating member 1 constitute a semiconductor module 200.

Next, the heat radiating member 1 will be described in more detail. FIG. 4 is a perspective view of the heat radiating member 1 according to an exemplary embodiment of the present disclosure.

As described above, the heat radiating member 1 can be installed in the liquid cooling jacket 100, and includes the base part 2 and the heat radiating fin part 10.

The base part 2 has a plate shape that extends in the first direction and the second direction and has a thickness in the third direction. The base part 2 is made of a metal having high thermal conductivity, such as a copper alloy.

The semiconductor elements 7A and the like (FIG. 3) are fixed on the insulating circuit board 8 disposed on a surface 22 of the base part 2 on the second side in the third direction.

The heat radiating fin part 10 is configured as a so-called stacked fin by disposing a plurality of fins (fin plates) 6 in the second direction. The fins 6 are each formed of a metal plate extending in the first direction, and formed of a copper plate, for example. The heat radiating fin part 10 is fixed to the surface 21 of the base part 2 on the first side in the third direction by brazing, for example. That is, the heat radiating member 1 includes the heat radiating fin part 10 formed by stacking the plurality of fins 6 in the second direction, the fins 6 protruding from the base part 2 toward the first side in the third direction and extending in the first direction.

The refrigerant WT flows into an end (upstream end) 10A of the heat radiating fin part 10 on the first side in the first direction, and flows through a flow path formed between the fins 6 adjacent to each other in the second direction toward the second side in the first direction to be discharged from an end (downstream end) 10B of the heat radiating fin part 10 on the second side in the first direction.

The end 10A of the heat radiating fin part 10 on the first side in the first direction is provided with protrusions 101 and 102. Each of the protrusions 101 and 102 is formed by extending an end of the fin 6 on the first side in the first direction toward the first side in the first direction. As a result, the protrusions 101 and 102 protrude toward the first side in the first direction. That is, the heat radiating fin part 10 includes at least one protrusion 101 or 102 protruding toward the first side in the first direction at the end 10A on the first side in the first direction, the end 10A allowing the refrigerant WT supplied through the liquid cooling jacket 100 to flow into the end 10A.

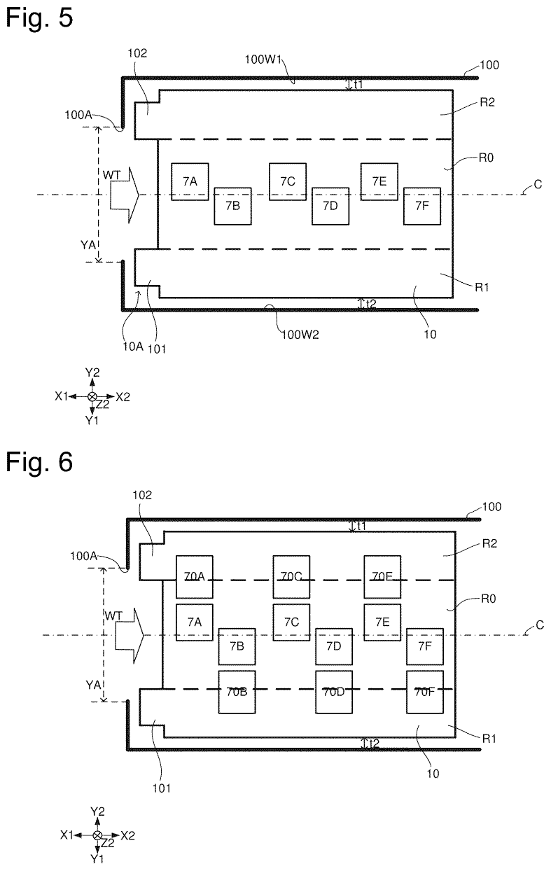

Next, various embodiments of a structure related to the protrusion such as the protrusion 101 or 102 will be described. FIG. 5 is a schematic plan view according to a first embodiment. FIG. 5 and FIGS. 6 to 8 described later are each a plan view viewed from the first side in the third direction.

As illustrated in FIG. 5, the liquid cooling jacket 100 includes side wall parts 100W1 and 100W2 disposed with gaps t1 and t2, respectively, in the second direction from respective ends of the heat radiating fin part 10 in the second direction. As illustrated in FIG. 2, the side wall parts 100W1 and 100W2 are provided in the second flow path 100B.

FIG. 5 illustrates a center line C passing through a center position of the heat radiating fin part 10 in the second direction. The protrusion 101 is disposed on the first side in the second direction with respect to the center line C. The protrusion 102 is disposed on the second side in the second direction with respect to the center line C.

As illustrated in FIG. 5, when viewed from the first side in the third direction, the heat radiating fin part 10 includes a central region R0 sandwiched by the protrusions 101 and 102 in the second direction, an end region R1 on the first side in the second direction with respect to the central region R0, and an end region R2 on the second side in the second direction with respect to the central region R0. The end region R1 includes the protrusion 101, and the end region R2 includes the protrusion 102.

As illustrated in FIG. 5, when viewed from the first side in the third direction, all of the semiconductor elements 7A and the like are disposed in the central region R0. As a result, when viewed from the first side in the third direction, all of the semiconductor elements 7A and the like are disposed closer to the center line C (the center position in the second direction) than each of the protrusions 101 and 102.

The refrigerant WT flowing from the first flow path 100A into the second flow path 100B flows into the end 10A of the heat radiating fin part 10 on the first side in the first direction. That is, the refrigerant WT flows into each of the central region R0, and the end regions R1 and R2. When the protrusions 101 and 102 are provided, a relationship of QA>QB>QC is satisfied, where flow rates of the central region R0, the end regions R1 and R2, and the gaps t1 and t2 are QA, QB, and QC, respectively. Although the refrigerant WT flowing through the gaps t1 and t2 hardly contributes to cooling of the semiconductor elements 7A and the like, the protrusions 101 and 102 interfere with the refrigerant WT flowing through the gaps t1 and t2. Thus, a flow rate of the refrigerant WT flowing through the central region R0 can be increased to improve cooling efficiency of the semiconductor elements 7A and the like.

FIG. 6 is a schematic plan view according to a second embodiment. The structure illustrated in FIG. 6 is different from that of the first embodiment in that semiconductor elements 70A, 70B, 70C, 70D, 70E, and 70F (referred to below as 70A and the like) are provided as semiconductor elements in addition to the semiconductor elements 7A and the like.

As illustrated in FIG. 6, when viewed from the first side in the third direction, a part of the semiconductor elements 70A, 70C, and 70E is disposed in the central region R0, and the other part is disposed in the end region R2. Additionally, when viewed from the first side in the third direction, a part of the semiconductor elements 70B, 70D, and 70F is disposed in the central region R0, and the other part is disposed in the end region R1.

That is, when viewed from the first side in the third direction, all of the semiconductor elements 7A and the like, all of the semiconductor elements 70A, 70C, and 70E, and some of the semiconductor elements 70B, 70D, and 70F are disposed closer to the center line C than the protrusion 101. Additionally, when viewed from the first side in the third direction, all of the semiconductor elements 7A and the like, some of the semiconductor elements 70A, 70C, and 70E, and all of the semiconductor elements 70B, 70D, and 70F are disposed closer to the center line C than the protrusion 102.

The protrusions 101 and 102 interfere with the refrigerant WT flowing through the gaps t1 and t2, respectively, to increase a flow rate of the refrigerant WT in the central region R0, so that cooling efficiency for cooling all of the semiconductor elements 7A and the like, and a part of the semiconductor elements 70A and the like, can be improved. Additionally, the refrigerant WT flowing through the end regions R1 and R2 can cool a part of the semiconductor elements 70A and the like.

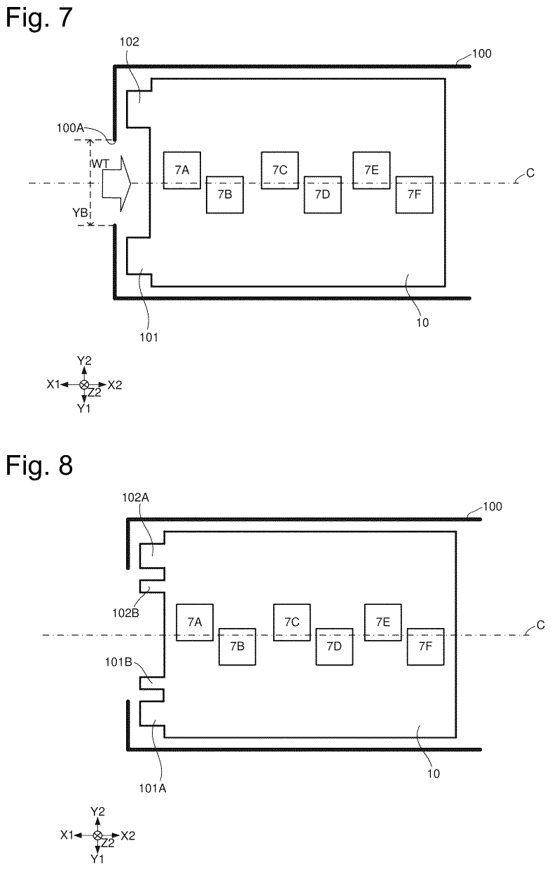

FIG. 7 is a schematic plan view according to a third embodiment. Although a second direction range YA (FIGS. 5 and 6) of the first flow path 100A overlaps a part of the protrusions 101 and 102 in the first and second embodiments, a second direction range YB of the first flow path 100A does not overlap the protrusions 101 and 102 in the present embodiment (FIG. 7).

As illustrated in FIG. 4, the protrusions 101 and 102 in the first to third embodiments are formed of a plurality of ends of the fin 6 the plurality of ends being extended toward the first side in the first direction and disposed side by side in the second direction. That is, at least one of the protrusions 101 and 102 is formed of a plurality of ends of the fin 6, the plurality of ends being on the first side in the first direction and disposed side by side in the second direction. As a result, the protrusions 101 and 102 can be improved in strength to reduce deformation of the protrusions 101 and 102 due to pressure of the refrigerant WT.

Alternatively, the protrusion may be formed by a single end of the fin 6 on the first side in the first direction.

The protrusions 101 and 102 in the first to third embodiments are provided on respective sides in the second direction with respect to the center line C (the center position in the second direction). This structure can interfere with the refrigerant WT flowing through the gaps t1 and t2 on respective sides in the second direction. Alternatively, the protrusion may be provided only on the first side in the second direction with respect to the center line C.

FIG. 8 is a schematic plan view according to a fourth embodiment. FIG. 8 illustrates the structure in which protrusions 101A and 101B are provided on the first side in the second direction with respect to the center line C, and protrusions 102A and 102B are provided on the second side in the second direction with respect to the center line C. That is, the two protrusions (101A, 101B) and the two protrusions (102A, 102B), or the plurality of protrusions, are provided on the same side in the second direction with respect to the center position in the second direction. The number of the plurality of protrusions may be three or more.

As a result, the protrusions 101B and 102B closer to the center line C (the center position in the second direction) block the refrigerant WT in advance, so that the amount of the refrigerant WT being not blocked by the protrusions 101A and 102A on the outermost side in the second direction can be reduced.

As in each of the above embodiments, when viewed from the first side in the third direction, at least one of the protrusions 101 and 102 is provided on at least one of the first side in the second direction and the second side in the second direction with respect to the center position of the heat radiating fin part 10 in the second direction. When viewed from the first side in the third direction, at least a part of the semiconductor elements (7A and the like, 70A and the like) provided on the base part 2 on the second side in the third direction is disposed closer to the center position in the second direction than the protrusions 101 and 102 provided closest to the center position in the second direction on the first side in the second direction or the second side in the second direction with respect to the center position in the second direction or on each of the first side in the second direction and the second side in the second direction with respect to the center position in the second direction. As a result, the cooling performance for cooling the semiconductor element can be improved by reducing the refrigerant WT in amount flowing through the gaps t1 and t2, and increasing the refrigerant WT in amount flowing into the heat radiating fin part 10 closer to the center position in the second direction than the protrusions 101 and 102.

The protrusion provided closest to the center position in the second direction corresponds to the protrusions 101 and 102 in the embodiments of FIGS. 5 to 7, and corresponds to the protrusions 101B and 102B in the embodiment of FIG. 8. When viewed from the first side in the third direction, at least a part of the semiconductor element may be disposed in a range sandwiched by the protrusions 101 and 102 or the protrusions 101B and 102B in the second direction. The center line C crosses the semiconductor elements 7A to 7F in FIGS. 5 to 8, but does not necessarily cross the semiconductor elements 7A to 7F.

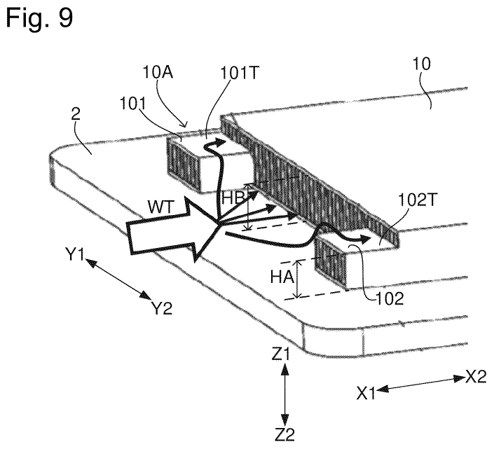

FIG. 9 is a partial perspective view of the heat radiating member 1 for illustrating a height of each of the protrusions 101 and 102. FIG. 9 illustrates the structure in which a third direction height HA of each of the protrusions 101 and 102 is lower than a third direction height HB of a part other than the protrusions 101 and 102 in the second direction at the end 10A of the heat radiating fin part 10 on the first side in the first direction. As a result, the refrigerant WT flows into the heat radiating fin part 10 after flowing on end surfaces 101T and 102T of the protrusions 101 and 102 in the third direction, so that a flow rate of the refrigerant WT in end regions (R1 and R2 in FIG. 5 or the like) including the protrusions 101 and 102 can be increased.

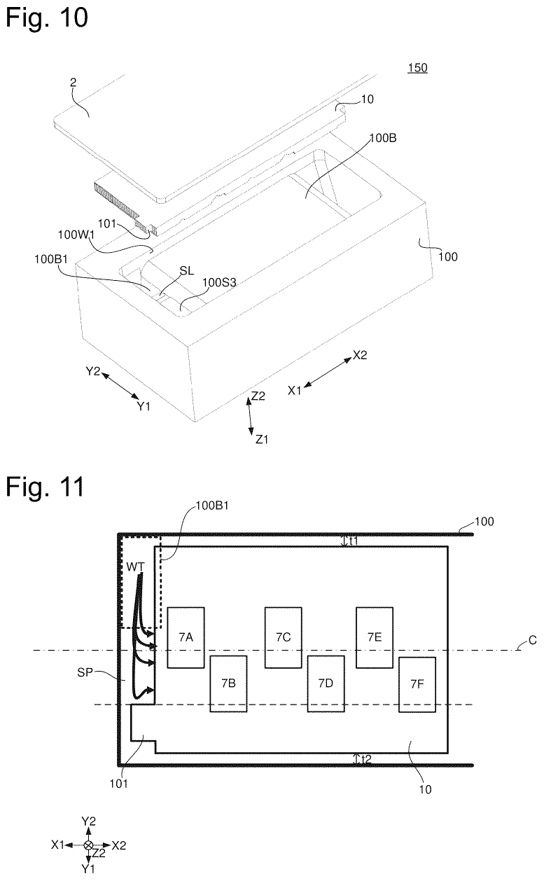

FIG. 10 is a partially exploded perspective view of a cooling device 150 according to a modification. FIG. 10 illustrates the structure in which a flow control part 100B1 is provided on an upstream side of the second flow path 100B in the liquid cooling jacket 100.

The flow control part 100B1 is formed as a recess recessed toward the first side in the third direction and includes a slope SL. The slope SL is inclined toward the first side in the second direction and the second side in the third direction. The flow control part 100B1 includes an opening (not illustrated) on the first side in the third direction and the second side in the second direction. The refrigerant WT having flowed into the flow control part 100B1 from the opening flows on the slope SL toward the first side in the second direction and the second side in the third direction, thereby controlling a flow of the refrigerant WT. After flowing on the slope SL, the refrigerant WT flows onto a bottom surface 100S3 connected to the slope SL and extending in the second direction. That is, the liquid cooling jacket 100 includes the flow control part 100B1 that causes the refrigerant WT having flowed into the liquid cooling jacket 100 to flow to the first side in the second direction.

Here, FIG. 11 is a schematic plan view illustrating the structure according to a modification as viewed from the first side in the third direction. The protrusion 101 is provided only on the first side in the second direction with respect to the center line C (the center position in the second direction) and is disposed on the first side in the second direction with respect to the flow control part 100B1. As a result, the refrigerant WT caused to flow toward the first side in the second direction by the flow control part 100B1 is prevented from flowing into the gap t2 on the first side in the second direction by the protrusion 101. The refrigerant WT is also prevented from flowing into the gap t1 on the second side in the second direction without providing a protrusion on the second side in the second direction because the refrigerant WT is caused to flow toward the first side in the second direction by the flow control part 100B1.

FIG. 11 illustrates an example in which all of the semiconductor elements 7A, 7C, and 7E are disposed closer to the center line C than the protrusion 101, and some of the semiconductor elements 7B, 7D, and 7F are disposed closer to the center line C than the protrusion 101. The refrigerant WT flowing through the gaps t1 and t2 is reduced in amount as described above, so that the refrigerant WT flowing into the heat radiating fin part 10 on the second side in the second direction from the protrusion 101 increases in amount, and thus the cooling efficiency of the semiconductor elements 7A and the like can be improved.

Between the flow control part 100B1 and the protrusion 101 in the second direction, a space SP is also provided between the bottom surface 100S3 (FIG. 10) of the liquid cooling jacket 100 and the base part 2 in the third direction. This structure allows the refrigerant WT with a flow direction controlled by the flow control part 100B1 to easily flow into the heat radiating fin part 10 using the space SP, and thus enables the cooling efficiency of the semiconductor elements 7A and the like to be improved.

The embodiment of the present disclosure has been described above. The scope of the present disclosure is not limited to the above embodiment. The present disclosure can be implemented by making various changes to the above embodiment without departing from the gist of the invention. The matters described in the above embodiment can be optionally combined together, as appropriate, as long as there is no inconsistency.

As described above, a cooling device according to an aspect of the present disclosure includes a liquid cooling jacket and a heat radiating member installed in the liquid cooling jacket, the heat radiating member including: a base part in a plate shape that extends in a first direction along a refrigerant flow direction and in a second direction orthogonal to the first direction and has a thickness in a third direction orthogonal to the first direction and the second direction; and a heat radiating fin part formed by stacking a plurality of fins in the second direction, the plurality of fins protruding from the base part toward a first side in the third direction and extending in the first direction, the liquid cooling jacket including side wall parts disposed with gaps in the second direction from respective ends of the heat radiating fin part in the second direction, and the heat radiating fin part including at least one protrusion protruding toward a first side in the first direction and being provided at an end of the heat radiating fin part on the first side in the first direction, the end allowing a refrigerant supplied through the liquid cooling jacket to flow into the end, wherein when viewed from the first side in the third direction, the at least one protrusion is provided on at least one of a first side in the second direction and a second side in the second direction with respect to a center position of the heat radiating fin part in the second direction, and when viewed from the first side in the third direction, at least a part of the semiconductor element provided on the base part on a second side in the third direction is disposed closer to the center position in the second direction than the protrusion provided closest to the center position in the second direction on the first side in the second direction or the second side in the second direction with respect to the center position in the second direction, or on each of the first side in the second direction and the second side in the second direction with respect to the center position in the second direction (first structure).

The first structure may be configured such that the at least one protrusion is formed of a plurality of ends of the fin, the plurality of ends being on the first side in the first direction and disposed side by side in the second direction (second structure).

The first or second structure may be configured such that a plurality of the protrusions is provided on an identical side in the second direction with respect to the center position in the second direction (third structure).

Any one of the first to third structures may be configured such that the protrusion has a height in the third direction, the height being lower than a height in the third direction of a part of the end on the first side in the first direction, the part excluding the protrusion in the second direction (fourth structure).

Any one of the first to fourth structures may be configured such that the protrusion is provided on each side in the second direction with respect to the center position in the second direction (fifth structure).

Any one of the first to fourth structures may be configured such that the liquid cooling jacket includes a flow control part that causes the refrigerant having flowed into the liquid cooling jacket to flow toward the first side in the second direction, and the protrusion is provided only on the first side in the second direction with respect to the center position in the second direction, and is disposed on the first side in the second direction with respect to the flow control part (sixth structure).

The sixth structure may be configured such that between the flow control part and the protrusion in the second direction, a space is provided between a bottom surface of the liquid cooling jacket and the base part in the third direction (seventh structure).

The present disclosure can be used for cooling semiconductor elements for various applications.

Features of the above-described preferred embodiments and the modifications thereof may be combined appropriately as long as no conflict arises.

While preferred embodiments of the present disclosure have been described above, it is to be understood that variations and modifications will be apparent to those skilled in the art without departing from the scope and spirit of the present disclosure. The scope of the present disclosure, therefore, is to be determined solely by the following claims.

What is claimed is:

1. A cooling device comprising:
a liquid cooling jacket; and
a heat radiating member installed in the liquid cooling jacket, the heat radiating member including:
a base part in a plate shape that extends in a first direction along a refrigerant flow direction and in a second direction orthogonal to the first direction and has a thickness in a third direction orthogonal to the first direction and the second direction; and
a heat radiating fin part formed by stacking a plurality of fins in the second direction, the plurality of fins protruding from the base part toward a first side in the third direction and extending in the first direction,
the liquid cooling jacket including side wall parts disposed with gaps in the second direction from respective ends of the heat radiating fin part in the second direction, and
the heat radiating fin part including at least one protrusion protruding toward a first side in the first direction and being provided at an end of the heat radiating fin part on the first side in the first direction, the end allowing a refrigerant supplied through the liquid cooling jacket to flow into the end,
wherein
when viewed from the first side in the third direction, the at least one protrusion is provided on at least one of a first side in the second direction and a second side in the second direction with respect to a center position of the heat radiating fin part in the second direction, and
when viewed from the first side in the third direction, at least a part of the semiconductor element provided on the base part on a second side in the third direction is disposed closer to the center position in the second direction than the protrusion provided closest to the center position in the second direction on the first side in the second direction or the second side in the second direction with respect to the center position in the second direction, or on each of the first side in the second direction and the second side in the second direction with respect to the center position in the second direction.

2. The cooling device according to claim 1, wherein
the at least one protrusion is formed of a plurality of ends of the fin, the plurality of ends being on the first side in the first direction and disposed side by side in the second direction.

3. The cooling device according to claim 1, wherein
a plurality of the protrusions is provided on an identical side in the second direction with respect to the center position in the second direction.

4. The cooling device according to claim 1, wherein
the protrusion has a height in the third direction, the height being lower than a height in the third direction of a part of the end on the first side in the first direction, the part excluding the protrusion in the second direction.

5. The cooling device according to claim 1, wherein
the protrusion is provided on each side in the second direction with respect to the center position in the second direction.

6. The cooling device according to claim 1, wherein
the liquid cooling jacket includes a flow control part that causes the refrigerant having flowed into the liquid cooling jacket to flow toward the first side in the second direction, and
the protrusion is provided only on the first side in the second direction with respect to the center position in the second direction, and is disposed on the first side in the second direction with respect to the flow control part.

7. The cooling device according to claim 6, wherein
between the flow control part and the protrusion in the second direction, a space is provided between a bottom surface of the liquid cooling jacket and the base part in the third direction.
